(19) United States
(12) Patent Application Publication
(10) Pub. No.: US 2026/0150701 A1
(43) Pub. Date: May 28, 2026

(54) SEMICONDUCTOR WAFER, METHOD FOR MANUFACTURING SEMICONDUCTOR WAFER, SEMICONDUCTOR CHIP, AND METHOD FOR MANUFACTURING SEMICONDUCTOR CHIP

(71) Applicant: Mitsubishi Electric Corporation, Tokyo (JP)

(72) Inventors: Takuma MATSUMOTO, Tokyo (JP); Takuyo NAKAMURA, Tokyo (JP); Kenichi HAMANO, Tokyo (JP); Kyohei AKIYOSHI, Tokyo (JP)

(73) Assignee: Mitsubishi Electric Corporation, Tokyo (JP)

(21) Appl. No.: 19/265,503

(22) Filed: Jul. 10, 2025

(30) Foreign Application Priority Data
Nov. 25, 2024 (JP) 2024-204448

(51) Int. Cl. H01L 23/544; H01L 21/78

(52) U.S. Cl. CPC H10W 46/00; H10P 54/00; H10W 46/201; H10W 46/401

(57) ABSTRACT

According to the present disclosure, a semiconductor wafer includes a semiconductor substrate, an epitaxial growth layer provided on an upper surface of the semiconductor substrate; and an identification part that is not exposed from the upper surface and a lower surface of the semiconductor substrate and is provided inside the semiconductor substrate, and is capable of identifying the semiconductor wafer.

### BACKGROUND

### Field

The present disclosure relates to a semiconductor wafer, a method for manufacturing a semiconductor wafer, a semiconductor chip, and a method for manufacturing a semiconductor chip.

### BACKGROUND

Semiconductor wafers may have identification information inscribed thereon in the form of characters, symbols, or the like for identifying the semiconductor wafer. The identification information is, for example, a lot number or a wafer number that serves as an ID (Identification) of the semiconductor wafer. By checking the identification part on which the identification information is engraved, product management, such as lot management, is performed.

Conventionally, as a method for forming an identification part on a semiconductor wafer, a method for forming an identification part on a semiconductor substrate by using a laser beam has been known. When the identification part is formed using the above-mentioned methods, the substrate is scraped away, destroying the crystal structure of the substrate.

JP 2004-235249 A discloses a semiconductor wafer having a semiconductor substrate, an identification part provided on the lower surface of the semiconductor substrate and capable of identifying the semiconductor wafer, and a transparent deposition layer deposited on the upper surface of the semiconductor substrate. It is further disclosed that the transparent deposition layer corresponds to an epitaxial growth layer, and that the identification part may be exposed from the lower surface of the semiconductor substrate.

In a semiconductor wafer, when an identification part is exposed from the upper surface of a semiconductor substrate, if a source gas is introduced in this state to form an epitaxial growth layer on the upper surface of the semiconductor substrate, the source gas may reach the portion of the upper surface of the semiconductor substrate where the identification part is exposed, causing crystal growth. Incidentally, even in the case where the identification part is exposed from the lower surface of the semiconductor substrate as in the semiconductor wafer described in JP 2004-235249 A, when a source gas is introduced in this state to form an epitaxial growth layer on the upper surface of the semiconductor substrate, the source gas flows around to the lower surface of the semiconductor substrate and reaches the portion of the lower surface of the semiconductor substrate where the identification part is exposed, which may cause crystal growth. As described above, when the identification part is exposed from the upper surface or lower surface of the semiconductor substrate, the crystal structure of the underlying semiconductor substrate is destroyed in the portion where the identification part is exposed, and therefore, when the source gas reaches that portion, crystals grow abnormally three-dimensionally. In this state, if the identification part is detected from above or below the semiconductor wafer, the abnormally grown crystals and the identification part overlap, resulting in a problem of poor visibility of the identification part.

### SUMMARY

The present disclosure has been made to solve the above-mentioned problems, and has an object to provide a semiconductor wafer and a method for manufacturing a semiconductor wafer that can suppress deterioration in visibility of an identification part that can identify a semiconductor wafer, even when an epitaxial growth layer is formed on the upper surface of a semiconductor substrate.

The features and advantages of the present disclosure may be summarized as follows.

According to an aspect of the present disclosure, a semiconductor wafer includes a semiconductor substrate, an epitaxial growth layer provided on an upper surface of the semiconductor substrate; and an identification part that is not exposed from the upper surface and a lower surface of the semiconductor substrate and is provided inside the semiconductor substrate, and is capable of identifying the semiconductor wafer.

According to an aspect of the present disclosure, a semiconductor chip includes a semiconductor substrate, an epitaxial growth layer provided on an upper surface of the semiconductor substrate, an opaque layer provided on the epitaxial growth layer; and an identification part that is not exposed from the upper surface and a lower surface of the semiconductor substrate and is provided inside the semiconductor substrate, and is capable of identifying the semiconductor chip.

According to an aspect of the present disclosure, a method for manufacturing a semiconductor wafer includes preparing a semiconductor substrate, forming an identification part inside the semiconductor substrate, the identification part being not exposed from a upper surface and a lower surface of the semiconductor substrate and capable of identifying the semiconductor wafer; and after the forming of the identification part, forming an epitaxial growth layer on the upper surface of the semiconductor substrate.

Other and further objects, features and advantages of the disclosure will appear more fully from the following description.

### BRIEF DESCRIPTION OF DRAWINGS

FIG. 1 is a schematic plan view of a semiconductor wafer before an opaque layer is formed according to Embodiment 1.

FIG. 2 is a schematic plan view of the semiconductor wafer after the opaque layer is formed according to Embodiment 1.

FIG. 3 is a schematic cross-sectional view of the semiconductor wafer according to Embodiment 1 taken along the line X-X in FIG. 2.

FIGS. 4-5 are schematic cross-sectional views of a semiconductor wafer according to the prior art.

FIG. 6 is schematic cross-sectional view showing an identification part forming step in the method for manufacturing a semiconductor wafer according to Embodiment 1.

FIG. 7 is a schematic cross-sectional view showing an epitaxial growth layer forming step in the method for manufacturing a semiconductor wafer according to Embodiment 1.

FIG. 8 is a schematic plan view of a semiconductor wafer according to Embodiment 2 before an opaque layer is formed.

FIG. 9 is a schematic plan view of the semiconductor wafer after the opaque layer is formed according to Embodiment 2.

FIG. 10 is a schematic cross-sectional view of the semiconductor wafer according to Embodiment 2 taken along the line X-X in FIG. 9.

FIG. 11A and FIG. 11B are schematic cross-sectional views showing an identification part forming step in a method for manufacturing a semiconductor wafer according to Embodiment 2.

FIG. 12A and FIG. 12B are schematic cross-sectional views showing a semiconductor substrate bonding step in the method for manufacturing the semiconductor wafer according to Embodiment 2.

FIG. 13 is a schematic cross-sectional view showing an epitaxial growth layer forming step in a method for manufacturing a semiconductor wafer according to Embodiment 2.

FIG. 14 is a schematic cross-sectional view of a semiconductor wafer according to Embodiment 3 taken along the line XX in FIG. 9.

FIG. 15 is a schematic cross-sectional view showing a boundary layer forming step in a method for manufacturing a semiconductor wafer according to Embodiment 3.

FIG. 16A and FIG. 16B are schematic cross-sectional views showing an identification part forming step in a method for manufacturing a semiconductor wafer according to Embodiment 3.

FIG. 17A and FIG. 17B are schematic cross-sectional views showing a semiconductor substrate bonding step in the method for manufacturing the semiconductor wafer according to Embodiment 3.

FIG. 18 is a schematic cross-sectional view showing an epitaxial growth layer forming step in the method for manufacturing the semiconductor wafer according to Embodiment 3.

### DESCRIPTION OF EMBODIMENTS

### <Introduction>

One side in a direction parallel to the depth direction of the semiconductor device is referred to as the “upper” side, and the other side as the “lower” side. Of the two main surfaces of a substrate, layer, or other member, one surface is referred to as the upper surface and the other surface is referred to as the lower surface. The directions of “upper” and “lower” are not limited to the direction of gravity or the directions when the semiconductor device is mounted.

In addition, the drawings are shown diagrammatically, and the relative sizes and positions of images shown in different drawings are not necessarily accurately depicted and may be changed as appropriate. In the following description, similar components are illustrated with the same reference numerals, and their names and functions are also the same. Therefore, detailed descriptions thereof may be omitted.

### Embodiment 1

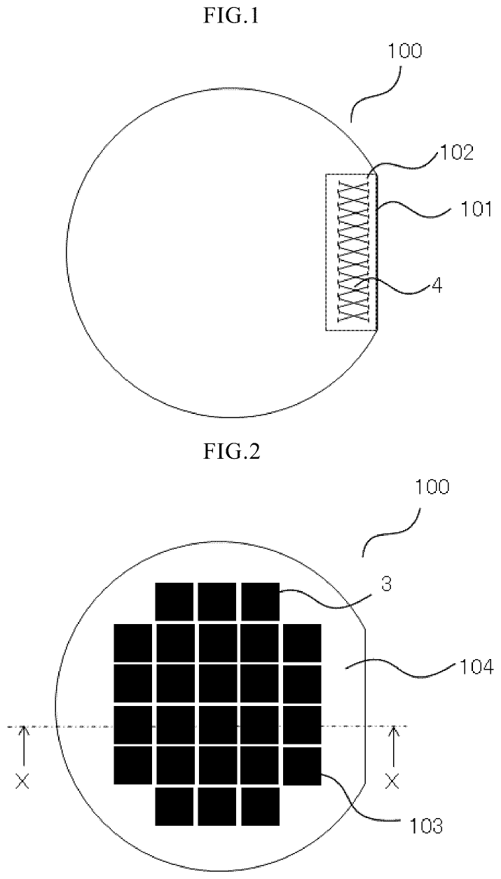

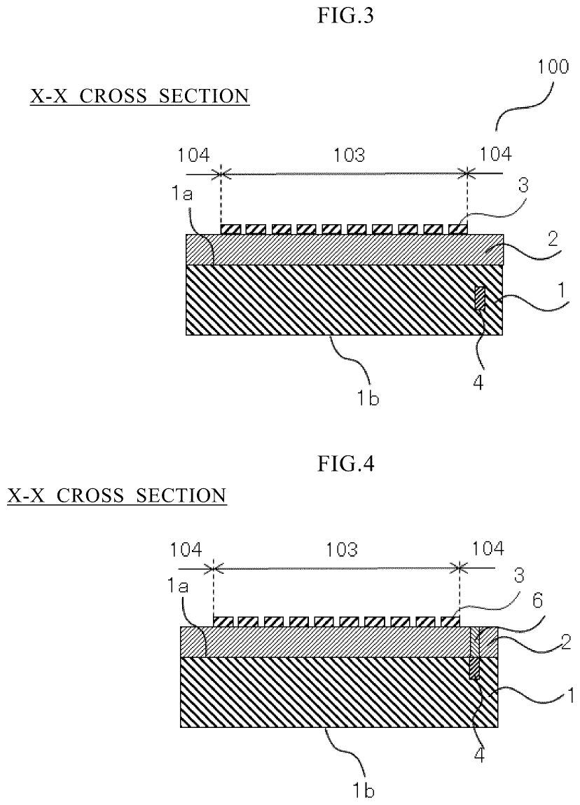

The first embodiment will be described below with reference to the drawings. FIG. 1 is a schematic plan view of a semiconductor wafer 100 according to Embodiment 1 before an opaque layer 3 is formed. FIG. 2 is a schematic plan view of the semiconductor wafer 100 according to Embodiment 1 after the opaque layer 3 has been formed. FIG. 3 is a schematic cross-sectional view of the semiconductor wafer 100 according to Embodiment 1 after the opaque layer 3 has been formed. FIG. 3 shows a cross section taken along the dot-dashed line X-X shown in FIG. 2. In FIG. 2, the identification part 4 is omitted.

The structure of a semiconductor wafer 100 will be described with reference to FIGS. 1-3. As shown in FIG. 3, the semiconductor wafer 100 includes a semiconductor substrate 1, an epitaxial growth layer 2, and the identification part 4.

As shown in FIGS. 1 and 3, an identification part 4, which will be described later, is engraved on the semiconductor wafer 100. As shown in FIG. 1, the identification part 4 is engraved in, for example, an engraving area 102 in the vicinity of an orientation flat 101 of the semiconductor wafer 100. The identification part 4 may be engraved in an engraving area provided near the notch portion, in addition to near the orientation flat 101. As shown in FIG. 1, the identification part 4 can be seen from above and below the semiconductor wafer 100. As shown in FIG. 2, the semiconductor wafer 100 may have an opaque layer region 103 where the opaque layer 3 (described later) is provided, and a peripheral region 104 where the opaque layer 3 is not provided. As shown in FIG. 2, the peripheral region 104 is provided to surround the opaque layer region 103. In the semiconductor wafer 100, the opaque layer region 103 where the opaque layer 3 is provided is a region used as a semiconductor device. The position at which the identification part 4 is provided is arbitrary as long as it can be controlled based on the orientation flat 101 or the notch.

The semiconductor substrate 1 is made of a semiconductor material that transmits almost all or a portion of the visible light range and allows the identification part 4 described below to be seen through, and is made of, for example, a semiconductor material such as silicon carbide (SiC). The semiconductor substrate 1 may be made of a semiconductor material that transmits light in wavelength bands other than visible light, such as infrared light and ultraviolet light, and allows the identification part 4, which will be described later, to be seen through, and may be made of a semiconductor material such as silicon (Si). In other words, the semiconductor substrate 1 is made of a semiconductor material that transmits the light and allows an identification part 4 (described later) to be seen through. As shown in FIG. 3, the semiconductor substrate 1 has an upper surface 1a and a lower surface 1b. It is preferable that the semiconductor substrate 1 be made of single crystal SiC. This can improve heat resistance, pressure resistance, and the like.

As shown in FIG. 3, the epitaxial growth layer 2 is provided on the upper surface 1a of the semiconductor substrate 1. In FIG. 3, the epitaxial growth layer 2 is provided over the entire upper surface 1a of the semiconductor substrate 1. However, when the identification part 4 is provided in the opaque layer region 103, the epitaxial growth layer 2 may not be provided on the upper surface 1a located in the peripheral region 104.

As shown in FIG. 3, an opaque layer 3 may be provided on top of the epitaxial growth layer 2. An interlayer insulating film may be provided between the opaque layer 3 and the epitaxial growth layer 2. The opaque layer 3 is a layer that does not transmit visible light, and is often a metal layer that functions as, for example, a gate electrode or an upper electrode, but may also be a resin layer. As shown in FIGS. 2 and 3, the opaque layer 3 is patterned into a predetermined shape, and therefore does not cover the entire upper surface of the semiconductor wafer 100.

As shown in FIG. 3, the identification part 4 is provided inside the semiconductor substrate 1 and is not exposed from the upper surface 1a and the lower surface 1b of the semiconductor substrate 1. The identification part 4 is a portion on the semiconductor substrate 1 where identification information capable of identifying the semiconductor wafer 100 is engraved in the form of characters, symbols, or the like. The identification information is, for example, a lot number or a wafer number that serves as an ID (Identification) of the semiconductor wafer. By checking the identification part 4, product management, such as lot management, can be performed. As the identification information, information such as which ingot the semiconductor wafer was sliced from, how the front and back surfaces of the semiconductor wafer were finished, etc. may be engraved to ensure traceability of the semiconductor wafer 100. Furthermore, as the identification information, parameters such as film thickness, concentration, defect information, and the presence or absence of a buffer layer as epitaxial growth conditions for forming the epitaxial growth layer may be engraved. As shown in FIGS. 1 and 3, the identification part 4 is preferably provided in the peripheral region 104 where the opaque layer 3 is not provided. For example, when a laser beam is used to form the identification part 4 in the opaque layer region 103 of the semiconductor substrate 1, the semiconductor substrate 1 is scraped away when forming the identification part 4, and the crystal structure of the semiconductor substrate 1 is destroyed, so that the region in which the identification part 4 is formed cannot be used as a semiconductor device. Therefore, by providing the identification part 4 in the peripheral region 104 where the opaque layer 3 is not provided, it is possible to secure an area for use as a semiconductor device, the area corresponding to the identification part 4. The identification part 4 is a portion where a part of the semiconductor substrate 1 is removed and the crystal structure of the semiconductor substrate 1 is destroyed.

A metal layer such as a lower electrode or a resin layer may be provided on the lower surface 1b of the semiconductor substrate 1.

In the manner described above, the semiconductor wafer 100 of the present embodiment is constructed. As in the semiconductor wafer 100 of this embodiment, the identification part 4 is configured to be not exposed from the upper surface 1a and the lower surface 1b of the semiconductor substrate 1, but is provided inside the semiconductor substrate 1, so that deterioration of the visibility of the identification part 4 can be suppressed even when an epitaxial growth layer 2 is deposited on the upper surface 1a of the semiconductor substrate 1. The reason for this will be explained below.

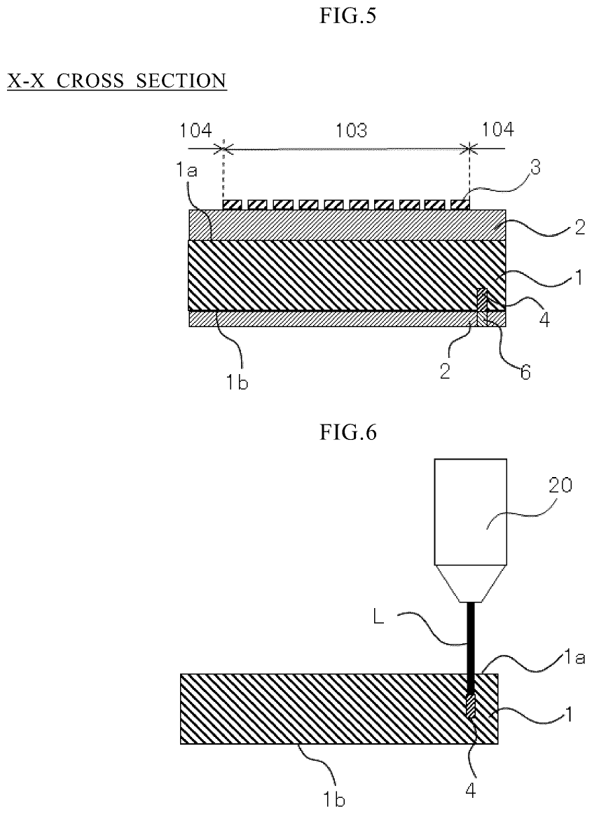

First, for comparison with the semiconductor wafer 100 of this embodiment, a semiconductor device of the prior art is shown in FIG. 4 as a comparative example 1. As shown in FIG. 4, in a conventional semiconductor wafer, the identification part 4 is provided inside the semiconductor substrate 1 with the identification part 4 exposed from the upper surface 1a of the semiconductor substrate 1. Therefore, when a source gas is introduced in this state to form an epitaxial growth layer 2 on the upper surface 1a of the semiconductor substrate 1, the source gas may reach the exposed portion of the identification part 4, causing crystal growth. In the portion of the upper surface 1a of the underlying semiconductor substrate 1 where the identification part 4 is exposed, the crystal structure is destroyed, and therefore a crystal 6 that has grown abnormally three-dimensionally is formed. In this state, if the identification part 4 is detected from above or below the semiconductor wafer, the abnormally grown crystals 6 and the identification part 4 will overlap, resulting in poor visibility of the identification part 4.

Moreover, a semiconductor device according to the prior art is shown in FIG. 5 as a comparative example 2. As shown in FIG. 5, in a conventional semiconductor wafer, the identification part 4 is provided inside the semiconductor substrate 1 with the identification part 4 exposed from the lower surface 1b of the semiconductor substrate 1. Therefore, when a source gas is introduced in this state to form an epitaxial growth layer 2 on the upper surface 1a of the semiconductor substrate 1, the source gas may flow around to the lower surface 1b of the semiconductor substrate 1 and reach the portion where the identification part 4 is exposed, which may result in crystal growth. In the portion of the lower surface 1b of the underlying semiconductor substrate 1 where the identification part 4 is exposed, the crystal structure is destroyed, and therefore a crystal 6 that has grown abnormally three-dimensionally is formed. In this state, if the identification part 4 is detected from above or below the semiconductor wafer, the abnormally grown crystals 6 and the identification part 4 will overlap, resulting in poor visibility of the identification part 4.

In contrast, in the semiconductor wafer 100 of the present embodiment, the identification part 4 is not exposed from the upper surface 1a and the lower surface 1b of the semiconductor substrate 1, but is provided inside the semiconductor substrate 1. Therefore, even if a source gas is introduced onto the upper surface 1a in order to form an epitaxial growth layer 2 on the upper surface 1a of the semiconductor substrate 1 and the source gas flows around to the lower surface 1b of the semiconductor substrate 1, the source gas does not reach the identification part 4. The portion where the crystal structure of the underlying semiconductor substrate 1 is destroyed is not exposed from the upper surface 1a and the lower surface 1b, but is located inside the semiconductor substrate 1, and therefore, crystal growth by the source gas occurs normally on the upper surface 1a and the lower surface 1b of the semiconductor substrate 1. Therefore, even when the epitaxial growth layer 2 is deposited on the upper surface of the semiconductor substrate 1, the deterioration of the visibility of the identification part 4 can be suppressed.

Next, an example of a method for detecting the identification part 4 of the semiconductor wafer 100 according to this embodiment will be described. The detection process of the identification part 4 using the detection method described below is carried out, for example, when detecting defects in the semiconductor wafer 100. In addition, the detection process of the identification part 4 using the detection method described below may be performed before the epitaxial layer formation step described later. In this way, the identification part 4 can be detected and epitaxial growth conditions suitable for the semiconductor wafer 100 can be set.

The identification part 4 is detected by observing the semiconductor wafer 100 from above using an optical microscope or a laser microscope, for example. Methods for detecting the identification part 4 include, for example, a method of detecting with the naked eye using an optical microscope as described in JP 2004-235249 A, and a method of detecting using a detection device equipped with a camera equipped with an optical or laser microscope. As described above, the semiconductor substrate 1 of the semiconductor wafer 100 of this embodiment is made of a semiconductor material that is transparent to light and allows the identification part 4 to be seen through. Therefore, even if the identification part 4 is not exposed from the upper surface 1a and the lower surface 1b and is provided inside the semiconductor substrate 1, the identification part 4 can be detected by the above detection method. When the identification part 4 is provided in the peripheral region 104, the identification part 4 can be detected from both the upper surface 1a and the lower surface 1b of the semiconductor substrate 1 by the above detection method. Furthermore, when the identification part 4 is provided in the opaque layer region 103 and is to be detected after the opaque layer 3 is provided, the identification part 4 may be detected from the lower surface 1b side of the semiconductor substrate 1 using the above-mentioned detection method. The identification part 4 may be detected using light other than visible light, such as infrared light or ultraviolet light. By doing so, even if the semiconductor substrate 1 is made of Si, which does not transmit visible light, the identification part 4 can be detected because Si transmits near-infrared light.

Next, a semiconductor chip produced from the semiconductor wafer 100 of this embodiment will be described. A semiconductor chip produced from a semiconductor wafer 100 includes a semiconductor substrate 1, an epitaxial growth layer 2 provided on an upper surface 1a of the semiconductor substrate 1, and an opaque layer 3 provided on the upper side of the epitaxial growth layer 2. In addition to the identification part 4 capable of identifying the semiconductor wafer 100, the semiconductor chip may be further provided with an identification part capable of identifying the semiconductor chip, the identification part being provided inside the semiconductor substrate 1 without being exposed from the upper surface 1a and the lower surface 1b of the semiconductor substrate 1. A plurality of identification parts may be provided for each region in which a semiconductor chip is formed. By doing so, even after the semiconductor wafer 100 is divided into a plurality of semiconductor chips, it is possible to identify which semiconductor wafer the semiconductor chip was divided from. The identification part 4 capable of identifying the semiconductor wafer 100 and the identification part capable of identifying the semiconductor chip may have the same identification information, or may have different identification information.

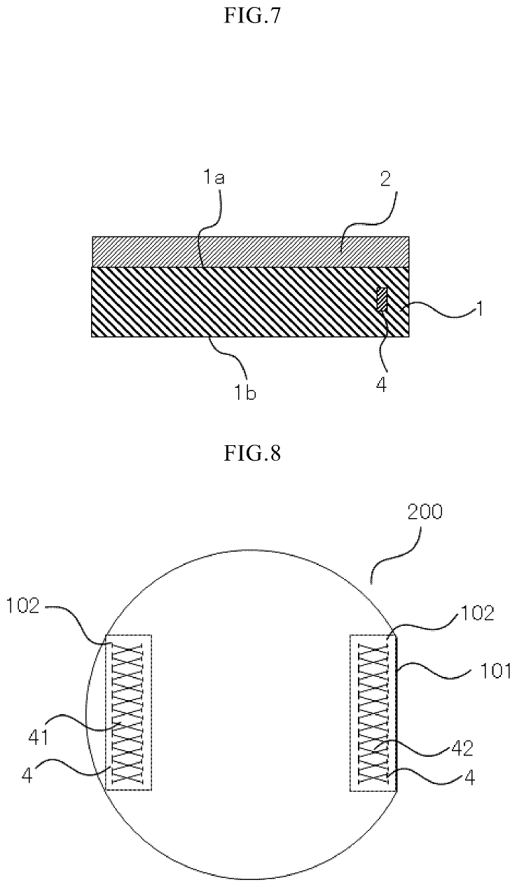

Next, a method for manufacturing the semiconductor wafer 100 according to this embodiment will be described with reference to FIGS. 6, 7. The method for manufacturing the semiconductor wafer 100 of this embodiment is basically the same as the conventional method for manufacturing a semiconductor wafer, except for the identification part forming step, and therefore some of the steps will not be described.

The method for manufacturing the semiconductor wafer 100 includes a semiconductor substrate preparation step, an identification part formation step, and an epitaxial growth layer formation step. The identification part forming step will be described with reference to FIG. 6, and the epitaxial growth layer forming step will be described with reference to Fig.

First, the semiconductor substrate preparation step will be described. A semiconductor substrate 1 having an upper surface 1a and a lower surface 1b is prepared. In this embodiment, one semiconductor substrate 1 is prepared.

Next, the identification part forming step will be described. As shown in FIG. 6, an identification part 4 that is not exposed from the upper surface 1a and the lower surface 1b of the semiconductor substrate 1 and that can identify the semiconductor wafer 100 is formed inside the semiconductor substrate 1. In the above-mentioned semiconductor substrate preparation step, the semiconductor substrate 1 on which the identification part 4 is formed in advance may be prepared.

As an example of a method for forming the identification part 4, a method for forming the identification part 4 on the semiconductor substrate 1 by laser processing will be described. For example, as shown in FIG. 6, a laser L is irradiated from the upper surface 1a side of the semiconductor substrate 1 by a laser irradiator 20, and an identification part 4 is formed by modifying a certain portion inside the semiconductor substrate 1 at a position that is not exposed from the upper surface 1a and the lower surface 1b of the semiconductor substrate 1. The identification part 4 may be formed by irradiating the laser L from the lower surface 1b side of the semiconductor substrate 1. Since the identification part 4 is formed by removing a part of the semiconductor substrate 1 using the above-mentioned method using a laser beam or the like, the crystal structure of the semiconductor substrate 1 is destroyed.

In order to improve the performance of the semiconductor device, the thickness of the semiconductor wafer 100 may be reduced by grinding the lower surface 1b side of the semiconductor wafer 100. Depending on the position where the identification part 4 is formed, the identification part 4 formed inside the semiconductor substrate 1 may also be removed when the semiconductor substrate 1 is ground. In that case, the identification part 4 may be formed again after the lower surface 1b of the semiconductor wafer 100 is ground. In addition, by taking into consideration the amount of grinding of the semiconductor wafer 100 in advance and appropriately adjusting the formation position of the identification part 4, it is possible to prevent the identification part 4 formed inside the semiconductor substrate 1 from being removed when the semiconductor substrate 1 is ground.

Next, the epitaxial growth layer forming step will be described. The epitaxial growth layer forming step is carried out after the identification part forming step, and as shown in FIG. 7, an epitaxial growth layer 2 is formed on the upper surface 1a of the semiconductor substrate 1. For example, the epitaxial growth layer 2 is formed on the upper surface 1a of the semiconductor substrate 1 by a CVD method. As described above, the identification part forming step is performed before the epitaxial growth layer forming step. In this way, by detecting the identification part 4 formed in the identification part formation step using the detection method described above, the epitaxial growth layer 2 can be formed under epitaxial growth conditions suitable for the semiconductor wafer 100.

Through the above-mentioned steps, the semiconductor wafer 100 is manufactured. As described above, the method for manufacturing the semiconductor wafer 100 of this embodiment includes an identification part formation step, in which an identification part 4 that is not exposed from the upper surface 1a and the lower surface 1b of the semiconductor substrate 1 and that can identify the semiconductor wafer 100 is formed inside the semiconductor substrate 1. This makes it possible to suppress deterioration in visibility of the identification part 4 even when the epitaxial growth layer 2 is formed on the upper surface of the semiconductor substrate 1 in the epitaxial growth layer formation step that is performed after the identification part formation step.

Furthermore, in the conventional semiconductor wafer manufacturing method, in the identification part formation step, the identification part 4 is formed at a position exposed from the upper surface 1a or the lower surface 1b of the semiconductor substrate 1. This generates dust when forming the identification part 4, and if the generated dust reaches the semiconductor substrate 1, it may result in a defective product. In contrast, in the semiconductor wafer 100 of this embodiment, the identification part 4 is not exposed from the upper surface 1a and the lower surface 1b of the semiconductor substrate 1, but is provided inside the semiconductor substrate 1. This makes it possible to prevent dust from being generated when forming the identification part 4 and to prevent dust from reaching the semiconductor substrate 1, thereby making it possible to prevent the occurrence of defective products.

Next, a method for manufacturing the semiconductor chip according to this embodiment will be described. The method for manufacturing a semiconductor chip according to this embodiment includes a dicing step of dicing the semiconductor wafer 100 to form a plurality of semiconductor chips. In the dicing process, the semiconductor wafer 100 is divided into semiconductor chips by a method for dividing a semiconductor wafer, such as blade dicing or laser dicing, thereby forming a plurality of semiconductor chips. After the dicing process, conventional semiconductor chip manufacturing processes such as a die bonding process are carried out.

In the above-mentioned identification part forming step, an identification part capable of identifying the semiconductor chip may be formed in the opaque layer region 103. Incidentally, a plurality of such identification parts may be formed for each region in which a semiconductor chip is formed. By doing so, even after the semiconductor wafer 100 is divided into a plurality of semiconductor chips in the above-mentioned dicing process, it is possible to identify which semiconductor wafer the semiconductor chip was divided from.

### Embodiment 2

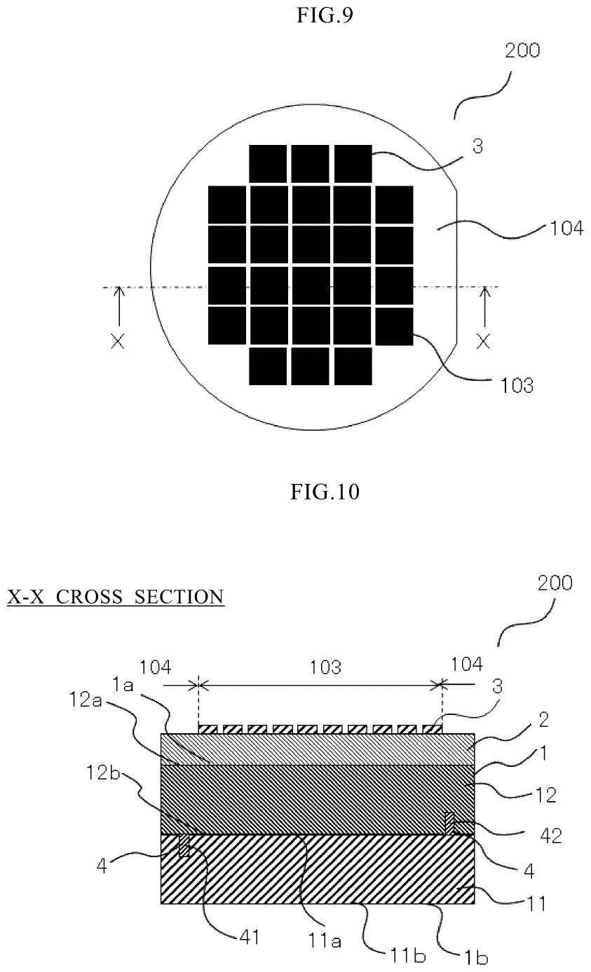

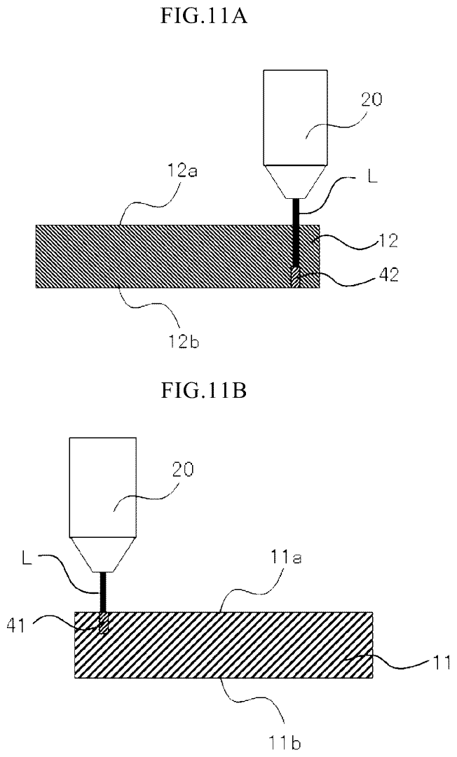

A semiconductor wafer 200 according to Embodiment 2 will be described with reference to FIGS. 8-10. FIG. 8 is a schematic plan view of a semiconductor wafer 200 according to Embodiment 2 before the opaque layer 3 is formed. FIG. 9 is a schematic plan view of the semiconductor wafer 200 according to Embodiment 2 after the opaque layer 3 has been formed. FIG. 10 is a schematic cross-sectional view of a semiconductor wafer 200 according to Embodiment 2 after an opaque layer 3 has been formed. FIG. 10 shows a cross section taken along the dot-dashed line X-X shown in FIG. 9. In FIG. 9, the identification part 4 is omitted.

The semiconductor wafer 200 of Embodiment 2 differs from Embodiment 1 in that the semiconductor substrate 1 is composed of a first semiconductor substrate 11 and a second semiconductor substrate 12 provided on an upper surface 11a of the first semiconductor substrate 11, as shown in FIG. 10. As shown in FIG. 10, the first semiconductor substrate 11 and the second semiconductor substrate 12 are collectively referred to as the semiconductor substrate 1, the upper surface 12a of the second semiconductor substrate 12 is referred to as the upper surface 1a of the semiconductor substrate 1, and the lower surface 11b of the first semiconductor substrate 11 is referred to as the lower surface 1b of the semiconductor substrate 1. The first semiconductor substrate 11 and the second semiconductor substrate 12 may each be made of single crystal SiC. This can improve the heat resistance. Also, for example, the second semiconductor substrate 12 may be made of single crystal SiC, and the first semiconductor substrate 11 may be made of polycrystalline SiC, single crystal Si, polycrystalline Si, sapphire, carbon, or the like. This allows the manufacturing costs of the semiconductor wafer 200 to be reduced compared to when the first semiconductor substrate 11 is made of single crystal SiC.

In the semiconductor wafer 200 according to Embodiment 2, an epitaxial growth layer 2 is provided on an upper surface 1a of a semiconductor substrate 1, as shown in FIG. 10. In detail, the epitaxial growth layer 2 is provided on the upper surface 12a of the second semiconductor substrate 12.

In the semiconductor wafer 200 of Embodiment 2, the identification part 4 is not exposed from the upper surface 1a and the lower surface 1b of the semiconductor substrate 1, but is provided inside the semiconductor substrate 1, as shown in FIG. 10. In detail, the identification part 4 is provided inside the semiconductor substrate 1 and is not exposed from the upper surface 12a of the second semiconductor substrate 12 and the lower surface 11b of the first semiconductor substrate 11. Furthermore, the identification part 4 may be provided on the lower surface 12b of the second semiconductor substrate 12 and on the upper surface 11a of the first semiconductor substrate 11 inside the semiconductor substrate 1. The identification part 4 provided on the upper surface 11a of the first semiconductor substrate 11 is referred to as a first identification part 41, and the identification part 4 provided on the lower surface 12b of the second semiconductor substrate 12 is referred to as a second identification part 42. As shown in FIG. 8, it is preferable that the first identification part 41 and the second identification part 42 are provided at positions that do not overlap with each other in a top view. As shown in FIG. 10, the first identification part 41 and the second identification part 42 are preferably provided in the peripheral region 104 where the opaque layer 3 is not provided.

In FIG. 10, the identification part 4 is provided on both the lower surface 12b of the second semiconductor substrate 12 and the upper surface 11a of the first semiconductor substrate 11, but it is sufficient that the identification part 4 is provided on at least one of the lower surface 12b of the second semiconductor substrate 12 or the upper surface 11a of the first semiconductor substrate 11. It is also preferable that the identification part 4 be provided only on the lower surface 12b of the second semiconductor substrate 12 and not on the upper surface 11a of the first semiconductor substrate 11.

In the manner described above, the semiconductor wafer 200 according to Embodiment 2 is constructed.

In the semiconductor wafer 200 of Embodiment 2, the semiconductor substrate 1 is composed of a first semiconductor substrate 11 and a second semiconductor substrate 12 provided on an upper surface 11a of the first semiconductor substrate 11, an epitaxial growth layer 2 is provided on an upper surface 12a of the second semiconductor substrate 12, and an identification part 4 is not exposed from an upper surface 12a of the second semiconductor substrate 12 and a lower surface 11b of the first semiconductor substrate 11, but is provided inside the semiconductor substrate 1. By doing so, even if the raw material gas is introduced onto the upper surface 12a of the second semiconductor substrate 12 and the raw material gas flows around to the lower surface 11b of the first semiconductor substrate 11, the identification part 4 is not exposed from the upper surface 12a of the second semiconductor substrate 12 and the lower surface 11b of the first semiconductor substrate 11, and is provided inside the semiconductor substrate 1. As a result, the raw material gas can be prevented from reaching the identification part 4, as in Embodiment 1. The portions of the underlying first semiconductor substrate 11 and second semiconductor substrate 12 where the crystal structures are destroyed are not exposed from the upper surface 12a of the second semiconductor substrate 12 and the lower surface 11b of the first semiconductor substrate 11, but are located inside the entire semiconductor substrate 1, and therefore, normal crystal growth occurs on the upper surface 12a of the second semiconductor substrate 12 and the lower surface 11b of the first semiconductor substrate 11. Therefore, even when the epitaxial growth layer 2 is deposited on the upper surface 12a of the second semiconductor substrate 12, the deterioration of the visibility of the identification part 4 can be suppressed.

Furthermore, in the semiconductor wafer 200 of Embodiment 2, when the identification part 4 is provided on both the second semiconductor substrate 12 and the first semiconductor substrate 11, as described above, it is desirable that the first identification part 41 and the second identification part 42 are provided at positions that do not overlap each other when viewed from above. This allows the identification parts 41 and 42 to be detected separately, and the identification information to be appropriately read. In addition, in the semiconductor wafer 200 of Embodiment 2, by providing the identification part 4 on the second semiconductor substrate 12 and not on the first semiconductor substrate 11, it is possible to make the first semiconductor substrate 11 easier to reuse.

Next, an example of a method for detecting the identification part 4 on the semiconductor wafer 200 according to Embodiment 2 will be described. For example, when the identification part 4 is provided on at least one of the lower surface 12b of the second semiconductor substrate 12 or the upper surface 11a of the first semiconductor substrate 11, and the identification part 4 is detected using only visible light, the identification part 4 can be detected if at least one of the first semiconductor substrate 11 or the second semiconductor substrate 12 is made of a semiconductor material that transmits visible light.

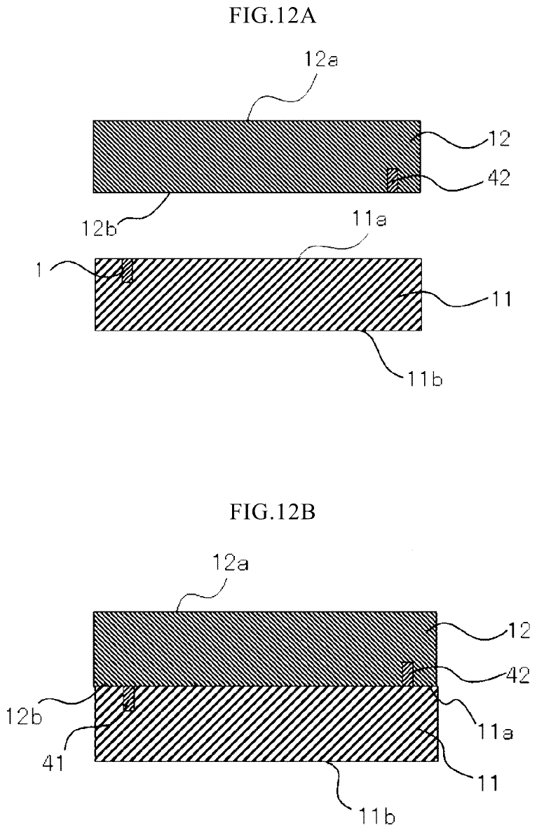

Next, a method for manufacturing the semiconductor wafer 200 according to Embodiment 2 will be described with reference to FIGS. 11-13. The method for manufacturing the semiconductor wafer 200 according to Embodiment 2 includes a semiconductor substrate preparation step, an identification part formation step, a semiconductor substrate bonding step, and an epitaxial growth layer formation step. The identification part formation step is explained in FIG. 11, the semiconductor substrate bonding step is explained in FIG. 12 and the epitaxial growth layer formation step is explained in FIG. 13. Note that the same parts as those in Embodiment 1 will be omitted from the description.

First, the semiconductor substrate preparation step will be described. As the semiconductor substrate 1, a first semiconductor substrate 11 and a second semiconductor substrate 12 are prepared.

Next, the identification part forming step will be described. In the identification part forming step, the identification part 4 is formed inside the semiconductor substrate 1 without being exposed from the upper surface 12a of the second semiconductor substrate 12 and the lower surface 11b of the first semiconductor substrate 11. As shown in FIG. 11A, in the second semiconductor substrate 12, the second identification part 42 may be formed on a lower surface 12b of the second semiconductor substrate 12 without being exposed on the upper surface 12a of the second semiconductor substrate 12, and as shown in FIG. 11B, in the first semiconductor substrate 11, the first identification part 41 may be formed on the upper surface 11a of the first semiconductor substrate 11 without being exposed on a lower surface 11b of the first semiconductor substrate 11. In Embodiment 2, both the first identification part 41 and the second identification part 42 are formed, but it is sufficient to form either the first identification part 41 or the second identification part 42, and the identification part 4 may be formed on at least one of the lower surface 12b of the second semiconductor substrate 12 or the upper surface 11a of the first semiconductor substrate 11. In the above-mentioned semiconductor substrate preparation step, the semiconductor substrate 1 on which the identification part 4 is formed in advance may be prepared.

For example, as shown in FIG. 11, the identification part 4 may be formed by irradiating the first semiconductor substrate 11 and the second semiconductor substrate 12 with a laser L by a laser irradiator 20. In the second semiconductor substrate 12, a laser L is irradiated from the upper surface 12a side of the second semiconductor substrate 12, and a second identification part 42 is formed by modifying a portion of the lower surface 12b side of the second semiconductor substrate 12 so that it is not exposed from the upper surface 12a of the second semiconductor substrate 12. The laser L may be irradiated from the lower surface 12b side of the second semiconductor substrate 12. In addition, in the first semiconductor substrate 11, a laser L is irradiated from the upper surface 11a side of the first semiconductor substrate 11, and a first identification part 41 is formed by modifying a portion of the upper surface 11a side of the first semiconductor substrate 11 so that it is not exposed from the lower surface 11b of the first semiconductor substrate 11. The laser L may be irradiated from the lower surface 11b side of the first semiconductor substrate 11.

Next, the semiconductor substrate bonding step will be described. As shown in FIG. 12A, first, the upper surface 11a of the first semiconductor substrate 11 and the lower surface 12b of the second semiconductor substrate 12 are aligned so as to face each other. Then, as shown in FIG. 12B, the lower surface 12b of the second semiconductor substrate 12 is bonded to the upper surface 11 a of the first semiconductor substrate 11. In Embodiment 2, the first semiconductor substrate 11 and the second semiconductor substrate 12 are directly bonded to each other.

Next, the epitaxial growth layer forming step will be described. The epitaxial growth layer forming step is carried out after the identification part forming step, and as shown in FIG. 13, the epitaxial growth layer 2 is formed on the upper surface 12a of the second semiconductor substrate 12. In addition, in the above-mentioned identification part forming process, when the identification part 4 is formed on at least one of the lower surface 12b of the second semiconductor substrate 12 or the upper surface 11a of the first semiconductor substrate 11, the epitaxial growth layer forming process is performed after the identification part forming process and the semiconductor substrate bonding step.

Through the above-described steps, the semiconductor wafer 200 is fabricated. As described above, the method for manufacturing the semiconductor wafer 200 of Embodiment 2 includes an identification part formation step, in which an identification part 4 capable of identifying the semiconductor wafer 200 is formed inside the semiconductor substrate 1 without being exposed from the upper surface 12a of the second semiconductor substrate 12 and the lower surface 11b of the first semiconductor substrate 11. The method also includes a semiconductor substrate bonding step, in which the lower surface 12b of the second semiconductor substrate 12 is bonded to the upper surface 11a of the first semiconductor substrate 11. By doing so, even when the epitaxial growth layer 2 is formed on the upper surface 12a of the second semiconductor substrate 12 in the epitaxial growth layer formation step performed after the identification part formation step, deterioration of the visibility of the identification part 4 can be suppressed.

Furthermore, in the method for manufacturing the semiconductor wafer 100 of Embodiment 1, since the semiconductor substrate 1 is made of a single piece, in the identification part formation step, in order to form the identification part 4 inside the semiconductor substrate 1 without exposing the identification part 4 from the upper surface 1a and the lower surface 1b of the semiconductor substrate 1, it is necessary to form the identification part 4 inside the single semiconductor substrate 1. Therefore, the method for forming the identification part 4 is limited to a method using a laser, for example. In contrast, in the method for manufacturing the semiconductor wafer 200 of Embodiment 2, the semiconductor substrate 1 is composed of two parts, that is, the first semiconductor substrate 11 and the second semiconductor substrate 12. Therefore, in the identification part forming process, the identification part 4 is formed on at least one of the lower surface 12b of the second semiconductor substrate 12 or the upper surface 11a of the first semiconductor substrate 11. In the semiconductor substrate bonding step, the lower surface 12b of the second semiconductor substrate 12 is bonded to the upper surface 11a of the first semiconductor substrate 11. This makes it possible to form the identification part 4 inside the semiconductor substrate 1 without being exposed from the upper surface 1a and the lower surface 1b of the semiconductor substrate 1. Therefore, compared to the method for manufacturing the semiconductor wafer 100 of Embodiment 1, the identification part 4 can be easily formed inside the semiconductor substrate 1 without being exposed from the upper surface 1a and the lower surface 1b of the semiconductor substrate 1. For example, the identification part 4 can be formed by a mechanical method such as cutting.

In addition, after the epitaxial growth layer formation step in the method for manufacturing the semiconductor wafer 200 of Embodiment 2, the semiconductor wafer 200 may be divided into an upper part and a lower part, and one of the divided semiconductor substrates 1 that does not have an epitaxial growth layer may be reused in a semiconductor substrate preparation step in a method for manufacturing another semiconductor wafer. At this time, the divided semiconductor substrate 1 may be reused as a first semiconductor substrate 11 of another semiconductor wafer, or may be reused as a second semiconductor substrate 12. In the manufacturing process of the semiconductor wafer 200, the thickness of the semiconductor wafer 200 may be reduced by grinding the lower surface 1b side of the semiconductor wafer 200. In this case, the portion of the semiconductor substrate 1 located on the lower surface 1b side is removed. In particular, when the semiconductor substrate 1 is made of single crystal SiC, which is relatively expensive, the manufacturing cost of the semiconductor wafer can be reduced by dividing the semiconductor wafer 200 and reusing the divided semiconductor substrates 1. Furthermore, in the identification part forming step in the method for manufacturing the semiconductor wafer 200, the identification part 4 may be formed only on the lower surface 12b of the second semiconductor substrate 12 and not on the upper surface 11a of the first semiconductor substrate 11, which makes it easier to reuse the first semiconductor substrate 11.

### Embodiment 3

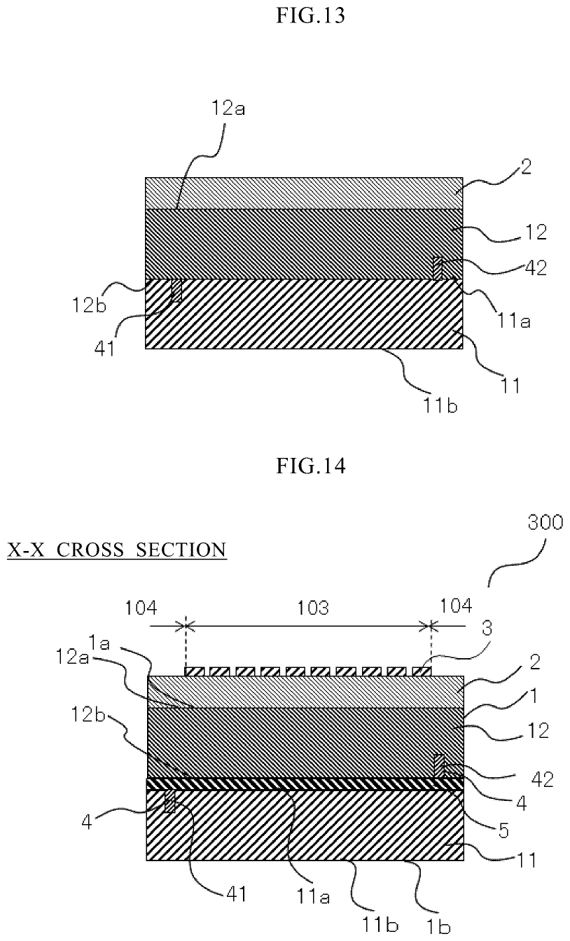

A semiconductor wafer 300 according to Embodiment 3 will be described with reference to FIG. 14. FIG. 14 is a schematic cross-sectional view of a semiconductor wafer 300 according to Embodiment 3 after an opaque layer 3 has been formed. Schematic plan views of the semiconductor wafer 300 according to Embodiment 3 before and after the opaque layer 3 is formed are omitted since they are similar to FIGS. 8 and 9, respectively. FIG. 14 shows a cross section taken along the dot-dashed line X-X shown in FIG. 9

As shown in FIG. 14, the semiconductor wafer 300 of Embodiment 3 differs from that of Embodiment 1 in that a semiconductor substrate 1 is composed of a first semiconductor substrate 11 and a second semiconductor substrate 12 provided on an upper surface 11a of the first semiconductor substrate 11. Another difference from Embodiment 2 is that a boundary layer 5 made of at least one of an organic material and an inorganic material is interposed between the upper surface 11a of the first semiconductor substrate 11 and the lower surface 12b of the second semiconductor substrate 12. As shown in FIG. 14, the first semiconductor substrate 11, the second semiconductor substrate 12, and the boundary layer 5 are collectively referred to as the semiconductor substrate 1, the upper surface 12a of the second semiconductor substrate 12 is referred to as the upper surface 1a of the semiconductor substrate 1, and the lower surface 11b of the first semiconductor substrate 11 is referred to as the lower surface 1b of the semiconductor substrate 1.

In the semiconductor wafer 300 according to Embodiment 3, an epitaxial growth layer 2 is provided on an upper surface 1a of a semiconductor substrate 1, as shown in FIG. 14. In detail, the epitaxial growth layer 2 is provided on the upper surface 12a of the second semiconductor substrate 12.

In the semiconductor wafer 300 of Embodiment 3, the identification part 4 is not exposed from the upper surface 1a and the lower surface 1b of the semiconductor substrate 1, but is provided inside the semiconductor substrate 1, as shown in FIG. 14. In detail, the identification part 4 is provided inside the semiconductor substrate 1 and is not exposed from the upper surface 12a of the second semiconductor substrate 12 and the lower surface 11b of the first semiconductor substrate 11. Furthermore, as shown in FIG. 14, the identification part 4 may be provided on the lower surface 12b of the second semiconductor substrate 12 and on the upper surface 11a of the first semiconductor substrate 11 inside the semiconductor substrate 1. The identification part 4 provided on the upper surface 11a of the first semiconductor substrate 11 is referred to as a first identification part 41, and the identification part 4 provided on the lower surface 12b of the second semiconductor substrate 12 is referred to as a second identification part 42. As shown in FIG. 14, it is preferable that the first identification part 41 and the second identification part 42 are provided at positions that do not overlap with each other in a top view. As shown in FIG. 14, the first identification part 41 and the second identification part 42 are preferably provided in the peripheral region 104 where the opaque layer 3 is not provided.

As in Embodiment 2, the identification part 4 may be provided on at least one of the lower surface 12b of the second semiconductor substrate 12 and the upper surface 11a of the first semiconductor substrate 11. It is also preferable that the identification part 4 be provided only on the lower surface 12b of the second semiconductor substrate 12 and not on the upper surface 11a of the first semiconductor substrate 11. The identification part 4 may be provided in the boundary layer 5.

The boundary layer 5 is preferably an amorphous layer. Furthermore, the boundary layer 5 may be made of, for example, an intermediate agent such as an adhesive, and may be anything that can facilitate bonding of the first semiconductor substrate 11 and the second semiconductor substrate.

In the manner described above, the semiconductor wafer 300 according to Embodiment 3 is constructed.

In the semiconductor wafer 300 of Embodiment 3, the semiconductor substrate 1 is composed of a first semiconductor substrate 11 and a second semiconductor substrate 12 provided on an upper surface 11a of the first semiconductor substrate 11, an epitaxial growth layer 2 is provided on an upper surface 12a of the second semiconductor substrate 12, and an identification part 4 is provided inside the semiconductor substrate 1 without being exposed from an upper surface 12a of the second semiconductor substrate 12 or a lower surface 11b of the first semiconductor substrate 11. By doing so, even if the raw material gas is introduced onto the upper surface 12a of the second semiconductor substrate 12 and the raw material gas flows around to the lower surface 11b of the first semiconductor substrate 11, the identification part 4 is not exposed from the upper surface 12a of the second semiconductor substrate 12 and the lower surface 11b of the first semiconductor substrate 11, and is provided inside the semiconductor substrate 1. As a result, the raw material gas can be prevented from reaching the identification part 4, as in Embodiment 1. The portions of the underlying first semiconductor substrate 11 and second semiconductor substrate 12 where the crystal structures are destroyed are not exposed from the upper surface 12a of the second semiconductor substrate 12 and the lower surface 11b of the first semiconductor substrate 11, but are located inside the entire semiconductor substrate 1, and therefore, normal crystal growth occurs on the upper surface 12a of the second semiconductor substrate 12 and the lower surface 11b of the first semiconductor substrate 11. Therefore, even when the epitaxial growth layer 2 is deposited on the upper surface 12a of the second semiconductor substrate 12, the deterioration of the visibility of the identification part 4 can be suppressed.

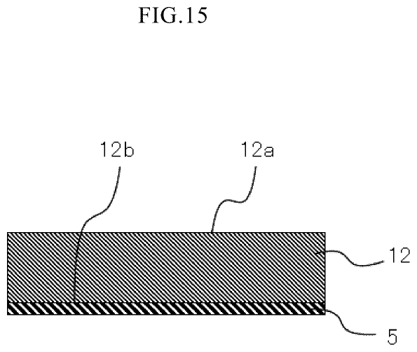

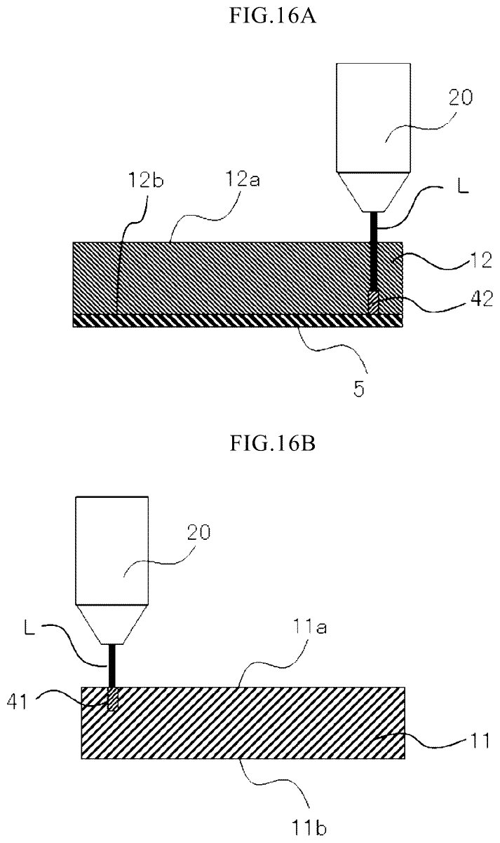

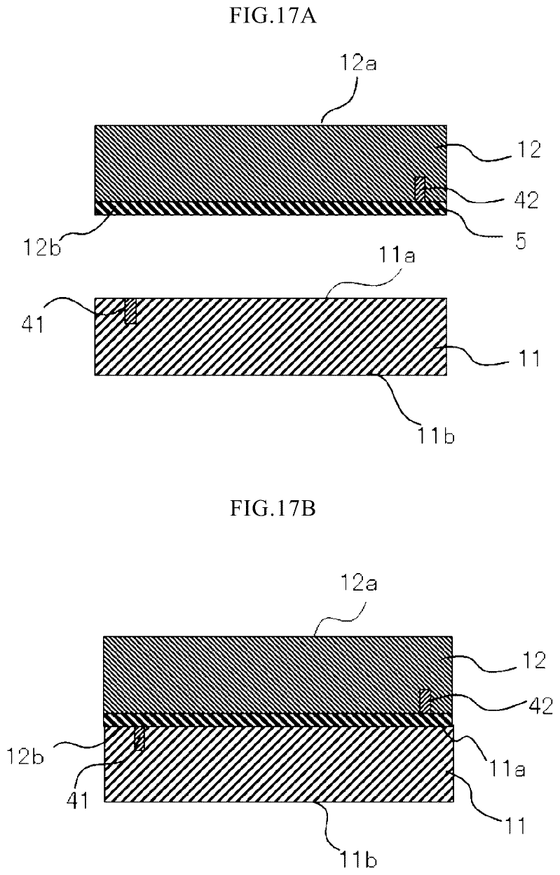

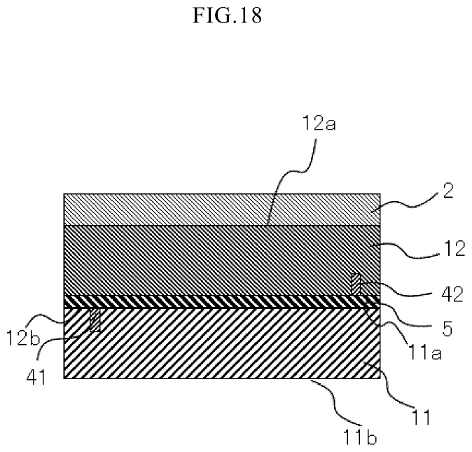

Next, a method for manufacturing the semiconductor wafer 300 according to Embodiment 3 will be described with reference to FIGS. 15-18. The method for manufacturing the semiconductor wafer 300 of Embodiment 3 includes a semiconductor substrate preparation step, a boundary layer formation step, an identification part formation step, a semiconductor substrate bonding step, and an epitaxial growth layer formation step. The boundary layer forming step will be described with reference to FIG. 15, the identification part forming step with reference to FIG. 16, the semiconductor substrate bonding step with reference to FIG. 17, and the epitaxial growth layer forming step with reference to FIG. 18. Note that the same parts as those in Embodiment 1 will be omitted from the description.

First, the semiconductor substrate preparation step will be described. As the semiconductor substrate 1, a first semiconductor substrate 11 and a second semiconductor substrate 12 are prepared.

Next, the boundary layer forming step will be described. A boundary layer 5 made of at least one of an organic material and an inorganic material is formed between the upper surface 11a of the first semiconductor substrate 11 and the lower surface 12b of the second semiconductor substrate 12. In Embodiment 2, as shown in FIG. 15, the boundary layer 5 made of at least one of an organic material and an inorganic material is formed on the lower surface 12b of the second semiconductor substrate 12. As described above, it is preferable to form an amorphous layer as the boundary layer 5, and an intermediate agent such as an adhesive may also be formed. The boundary layer 5 made of at least one of an organic material and an inorganic material may be formed on the upper surface 11a of the first semiconductor substrate 11. In the above-mentioned semiconductor substrate preparation step, the semiconductor substrate 1 on which the boundary layer 5 has been formed in advance may be prepared.

Next, the identification part forming step will be described. In the identification part forming step, the identification part 4 is formed inside the semiconductor substrate 1 without being exposed from the upper surface 12a of the second semiconductor substrate 12 and the lower surface 11b of the first semiconductor substrate 11. As shown in FIG. 16A, in the second semiconductor substrate 12, an identification part 42 may be formed on the lower surface 12b of the second semiconductor substrate 12 without being exposed on the upper surface 12a of the second semiconductor substrate 12, and as shown in FIG. 16B, in the first semiconductor substrate 11, an identification part 41 may be formed on the upper surface 11a of the first semiconductor substrate 11 without being exposed on the lower surface 11b of the first semiconductor substrate 11. In Embodiment 2, both the first identification part 41 and the second identification part 42 are formed, but it is sufficient to form either the first identification part 41 or the second identification part 42, and the identification part 4 may be formed on at least one of the lower surface 12b of the second semiconductor substrate 12 or the upper surface 11a of the first semiconductor substrate 11. In the above-described semiconductor substrate preparation step, the semiconductor substrate 1 on which the identification part 4 and the boundary layer 5 are formed in advance may be prepared. In FIG. 16A, the identification part 42 is formed on the second semiconductor substrate 12 on which the boundary layer 5 is formed. However, it is also possible to first form the identification part 42 on the second semiconductor substrate 12, and then form the boundary layer 5 on the second semiconductor substrate 12 on which the identification part 42 is formed.

For example, as shown in FIG. 16, the identification part 4 may be formed by irradiating the first semiconductor substrate 11 and the second semiconductor substrate 12 with a laser L by a laser irradiator 20. In the second semiconductor substrate 12, a laser L is irradiated from the upper surface 12a side of the second semiconductor substrate 12, and a second identification part 42 is formed by modifying a portion of the lower surface 12b side of the second semiconductor substrate 12 so that it is not exposed from the upper surface 12a of the second semiconductor substrate 12. The laser L may be irradiated from the lower surface 12b side of the second semiconductor substrate 12. In addition, in the first semiconductor substrate 11, a laser L is irradiated from the upper surface 11a side of the first semiconductor substrate 11, and a first identification part 41 is formed by modifying a portion of the upper surface 11a side of the first semiconductor substrate 11 so that it is not exposed from the lower surface 11b of the first semiconductor substrate 11. The laser L may be irradiated from the lower surface 11b side of the first semiconductor substrate 11. In FIG. 16A, the laser L is irradiated onto the inside of the second semiconductor substrate 12 to form the second identification part 42 inside the second semiconductor substrate 12, but the laser L may be irradiated onto the boundary layer 5 to form the second identification part 42 in the boundary layer 5. Even in such a case, the identification part 4 can be formed inside the semiconductor substrate 1 without being exposed from the upper surface 12a of the second semiconductor substrate 12 and the lower surface 11b of the first semiconductor substrate 11.

Next, the semiconductor substrate bonding step will be described. As shown in FIG. 17A, first, the upper surface 11a of the first semiconductor substrate 11 and the lower surface 12b of the second semiconductor substrate 12 are aligned so as to face each other. Then, as shown in FIG. 17B, the lower surface 12b of the second semiconductor substrate 12 is bonded to the upper surface 11a of the first semiconductor substrate 11. In Embodiment 3, the first semiconductor substrate 11 and the second semiconductor substrate 12 are indirectly bonded together via a boundary layer 5 made of an intermediate agent such as an adhesive. When the first semiconductor substrate 11 and the second semiconductor substrate 12 are directly bonded to each other, a boundary layer 5 may be interposed between the first semiconductor substrate 11 and the second semiconductor substrate 12. For example, in room temperature bonding, an amorphous layer serving as the boundary layer 5 may be formed in at least one of the first semiconductor substrate 11 and the second semiconductor substrate 12. Therefore, the first semiconductor substrate 11 and the second semiconductor substrate 12 may be bonded at room temperature with an amorphous layer as the boundary layer 5 interposed therebetween.

Next, the epitaxial growth layer forming step will be described. The epitaxial growth layer forming step is carried out after the identification part forming step, and as shown in FIG. 18, the epitaxial growth layer 2 is formed on the upper surface 12a of the second semiconductor substrate 12. In addition, when the identification part 4 is formed on at least one of the lower surface 12b of the second semiconductor substrate 12 or the upper surface 11a of the first semiconductor substrate 11 in the identification part formation step, the epitaxial growth layer formation step is performed after the identification part formation step and the semiconductor substrate bonding step. However, for example, if the identification part 4 is formed on the lower surface 12b of the second semiconductor substrate 12 in the identification part formation step and the boundary layer 5 is formed on the lower surface 12b of the second semiconductor substrate 12 in the boundary layer formation step, the identification part 4 will not be exposed on the lower surface 12b of the second semiconductor substrate 12, and this is not the case.

Through the above-described steps, the semiconductor wafer 300 is fabricated. As described above, the method for manufacturing the semiconductor wafer 300 of embodiment 3 includes an identification part formation step, in which an identification part 4 that is not exposed from the upper surface 12a of the second semiconductor substrate 12 and the lower surface 11b of the first semiconductor substrate 11 and that can identify the semiconductor wafer 300 is formed inside the semiconductor substrate 1. The method also includes a semiconductor substrate bonding step, in which the lower surface 12b of the second semiconductor substrate 12 is bonded to the upper surface 11a of the first semiconductor substrate 11. By doing so, even when the epitaxial growth layer 2 is formed on the upper surface 12a of the second semiconductor substrate 12 in the epitaxial growth layer formation step performed after the identification part formation step, deterioration of the visibility of the identification part 4 can be suppressed.

As described above, the method for manufacturing the semiconductor wafer 300 of Embodiment 3 includes a boundary layer formation step, in which a boundary layer 5 made of at least one of an organic material and an inorganic material is formed between the upper surface 11a of the first semiconductor substrate 11 and the lower surface 12b of the second semiconductor substrate 12. By doing so, in the semiconductor substrate bonding step, the first semiconductor substrate 11 and the second semiconductor substrate 12 can be bonded by the boundary layer 5 made of at least one of an organic material and an inorganic material, so that bonding of the first semiconductor substrate 11 and the second semiconductor substrate 12 can be performed more easily than in Embodiment 2.

As described above, it is preferable to form an amorphous layer as the boundary layer 5 in the boundary layer forming step. By doing so, in the semiconductor substrate bonding step, depending on the materials of the first semiconductor substrate 11 and the second semiconductor substrate 12, it becomes possible to bond the first semiconductor substrate 11 and the second semiconductor substrate 12 at room temperature. For example, when the first semiconductor substrate 11 and the second semiconductor substrate 12 are made with single crystal SiC, they can be bonded at room temperature. When the first semiconductor substrate 11 and the second semiconductor substrate 12 are bonded at room temperature, the bonding can be performed without the use of an intermediate agent such as an adhesive, so that deterioration of quality due to deterioration of the intermediate agent over time can be suppressed.

The configurations shown in the above embodiments are merely examples of the contents of the present disclosure, and may be combined with other known techniques. In addition, the embodiments and the modifications can be combined with each other. Furthermore, it is possible to omit or modify parts of the configuration without departing from the gist of the present disclosure.

Various aspects of the present disclosure are summarized below as appendices.

### (Appendix 1)

A semiconductor wafer comprising:
a semiconductor substrate;
an epitaxial growth layer provided on an upper surface of the semiconductor substrate; and
an identification part that is not exposed from the upper surface and a lower surface of the semiconductor substrate and is provided inside the semiconductor substrate, and is capable of identifying the semiconductor wafer.

### (Appendix 2)

The semiconductor wafer according to appendix 1, wherein
the semiconductor substrate includes a first semiconductor substrate and a second semiconductor substrate provided on an upper surface of the first semiconductor substrate,
the epitaxial growth layer is provided on an upper surface of the second semiconductor substrate, and
the identification part is not exposed from the upper surface of the second semiconductor substrate and a lower surface of the first semiconductor substrate, and is provided inside the semiconductor substrate.

### (Appendix 3)

The semiconductor wafer according to appendix 2, wherein the identification part is provided on at least one of a lower surface of the second semiconductor substrate and the upper surface of the first semiconductor substrate.

### (Appendix 4)

The semiconductor wafer according to appendix 2 of 3, wherein
the identification part includes a first identification part provided on the upper surface of the first semiconductor substrate and a second identification part provided on a lower surface of the second semiconductor substrate, and
the first identification part and the second identification part are provided at positions not overlapping each other in a top view.

### (Appendix 5)

The semiconductor wafer according to appendix 3, wherein the identification part is provided only on the lower surface of the second semiconductor substrate.

### (Appendix 6)

The semiconductor wafer according to any one of appendixes 2 to 5, wherein a boundary layer made of at least one of an organic material and an inorganic material is interposed between the upper surface of the first semiconductor substrate and a lower surface of the second semiconductor substrate.

### (Appendix 7)

The semiconductor wafer according to appendix 6, wherein the identification part is provided in the boundary layer.

### (Appendix 8)

The semiconductor wafer according to appendix 6 or 7, wherein the boundary layer is an amorphous layer.

### (Appendix 9)

The semiconductor wafer according to any one of appendixes 1 to 8, further comprising an opaque layer provided on the epitaxial growth layer, wherein
the semiconductor substrate has an opaque layer region in which the opaque layer is provided and a peripheral region in which the opaque layer is not provided, and the identification part is provided in the peripheral region.

### (Appendix 10)

The semiconductor wafer according to any one of appendixes 1 to 9, wherein the semiconductor substrate is made with SiC.

### (Appendix 11)

A semiconductor chip comprising:
a semiconductor substrate;
an epitaxial growth layer provided on an upper surface of the semiconductor substrate;
an opaque layer provided on the epitaxial growth layer; and
an identification part that is not exposed from the upper surface and a lower surface of the
semiconductor substrate and is provided inside the semiconductor substrate, and is capable of identifying the semiconductor chip.

### (Appendix 12)

A method for manufacturing a semiconductor wafer, the method comprising:
preparing a semiconductor substrate;
forming an identification part inside the semiconductor substrate, the identification part being not exposed from a upper surface and a lower surface of the semiconductor substrate and capable of identifying the semiconductor wafer; and
after the forming of the identification part, forming an epitaxial growth layer on the upper surface of the semiconductor substrate.

### (Appendix 13)

The method for manufacturing a semiconductor wafer according to appendix 12, wherein in the forming of the identification part, modifying an inside of the semiconductor substrate by laser processing to form the identification part.

### (Appendix 14)

The method for manufacturing a semiconductor wafer according to appendix 12 or 13, wherein
the preparing of the semiconductor substrate includes preparing a first semiconductor substrate and a second semiconductor substrate as the semiconductor substrate,
the forming of the identification part includes forming the identification part inside the semiconductor substrate without being exposed from an upper surface of the second semiconductor substrate and a lower surface of the first semiconductor substrate,
the method further comprising bonding a lower surface of the second semiconductor substrate to an upper surface of the first semiconductor substrate, and
the forming of the epitaxial growth layer includes forming the epitaxial growth layer on the upper surface of the second semiconductor substrate.

### (Appendix 15)

The method for manufacturing a semiconductor wafer according to appendix 14, wherein
the forming of the identification part includes forming the identification part on at least one of the lower surface of the second semiconductor substrate and the upper surface of the first semiconductor substrate, and
the forming of the epitaxial growth layer is performed after the forming of the identification part and the bonding.

### (Appendix 16)

The method for manufacturing a semiconductor wafer according to appendix 14, further comprising forming a boundary layer made of at least one of an organic material and an inorganic material between the upper surface of the first semiconductor substrate and the lower surface of the second semiconductor substrate.

### (Appendix 17)

A method for manufacturing a semiconductor chip, the method comprising:
dicing the semiconductor wafer manufactured by the method for manufacturing a semiconductor wafer according to any one of appendixes 12 to 16 to form a plurality of semiconductor chips.

According to the semiconductor wafer and the method for manufacturing the semiconductor wafer disclosed herein, even when an epitaxial growth layer is deposited on the upper surface of the semiconductor substrate, deterioration in visibility of an identification part that can identify the semiconductor wafer can be suppressed. Obviously many modifications and variations of the present disclosure are possible in the light of the above teachings. It is therefore to be understood that within the scope of the

appended claims the disclosure may be practiced otherwise than as specifically described. The entire disclosure of a Japanese Patent Application No. 2024-204448, filed on Nov. 25, 2024 including specification, claims, drawings and summary, on which the Convention priority of the present application is based, are incorporated herein by reference in its entirety.

1. A semiconductor wafer comprising:
a semiconductor substrate;
an epitaxial growth layer provided on an upper surface of the semiconductor substrate; and
an identification part that is not exposed from the upper surface and a lower surface of the semiconductor substrate and is provided inside the semiconductor substrate, and is capable of identifying the semiconductor wafer.

2. The semiconductor wafer according to claim 1, wherein
the semiconductor substrate includes a first semiconductor substrate and a second semiconductor substrate provided on an upper surface of the first semiconductor substrate,
the epitaxial growth layer is provided on an upper surface of the second semiconductor substrate, and
the identification part is not exposed from the upper surface of the second semiconductor substrate and a lower surface of the first semiconductor substrate, and is provided inside the semiconductor substrate.

3. The semiconductor wafer according to claim 2, wherein the identification part is provided on at least one of a lower surface of the second semiconductor substrate and the upper surface of the first semiconductor substrate.

4. The semiconductor wafer according to claim 2, wherein
the identification part includes a first identification part provided on the upper surface of the first semiconductor substrate and a second identification part provided on a lower surface of the second semiconductor substrate, and
the first identification part and the second identification part are provided at positions not overlapping each other in a top view.

5. The semiconductor wafer according to claim 3, wherein the identification part is provided only on the lower surface of the second semiconductor substrate.

6. The semiconductor wafer according to claim 2, wherein a boundary layer made of at least one of an organic material and an inorganic material is interposed between the upper surface of the first semiconductor substrate and a lower surface of the second semiconductor substrate.

7. The semiconductor wafer according to claim 6, wherein the identification part is provided in the boundary layer.

8. The semiconductor wafer according to claim 6, wherein the boundary layer is an amorphous layer.

9. The semiconductor wafer according to claim 1, further comprising an opaque layer provided on the epitaxial growth layer, wherein
the semiconductor substrate has an opaque layer region in which the opaque layer is provided and a peripheral region in which the opaque layer is not provided, and
the identification part is provided in the peripheral region.

10. The semiconductor wafer according to claim 1, wherein the semiconductor substrate is made with SiC.

11. A semiconductor chip comprising:
a semiconductor substrate;
an epitaxial growth layer provided on an upper surface of the semiconductor substrate;
an opaque layer provided on the epitaxial growth layer; and
an identification part that is not exposed from the upper surface and a lower surface of the semiconductor substrate and is provided inside the semiconductor substrate, and is capable of identifying the semiconductor chip.

12. A method for manufacturing a semiconductor wafer, the method comprising:
preparing a semiconductor substrate;
forming an identification part inside the semiconductor substrate, the identification part being not exposed from a upper surface and a lower surface of the semiconductor substrate and capable of identifying the semiconductor wafer; and
after the forming of the identification part, forming an epitaxial growth layer on the upper surface of the semiconductor substrate.

13. The method for manufacturing a semiconductor wafer according to claim 12, wherein in the forming of the identification part, modifying an inside of the semiconductor substrate by laser processing to form the identification part.

14. The method for manufacturing a semiconductor wafer according to claim 12, wherein
the preparing of the semiconductor substrate includes preparing a first semiconductor substrate and a second semiconductor substrate as the semiconductor substrate,
the forming of the identification part includes forming the identification part inside the semiconductor substrate without being exposed from an upper surface of the second semiconductor substrate and a lower surface of the first semiconductor substrate,
the method further comprising bonding a lower surface of the second semiconductor substrate to an upper surface of the first semiconductor substrate, and
the forming of the epitaxial growth layer includes forming the epitaxial growth layer on the upper surface of the second semiconductor substrate.

15. The method for manufacturing a semiconductor wafer according to claim 14, wherein
the forming of the identification part includes forming the identification part on at least one of the lower surface of the second semiconductor substrate and the upper surface of the first semiconductor substrate, and
the forming of the epitaxial growth layer is performed after the forming of the identification part and the bonding.

16. The method for manufacturing a semiconductor wafer according to claim 14, further comprising forming a boundary layer made of at least one of an organic material and an inorganic material between the upper surface of the first semiconductor substrate and the lower surface of the second semiconductor substrate.

17. A method for manufacturing a semiconductor chip, the method comprising:
dicing the semiconductor wafer manufactured by the method for manufacturing a semiconductor wafer according to claim 12 to form a plurality of semiconductor chips.
